(19) United States
(12) Patent Application Publication
(10) Pub. No.: US 2025/0080067 A1
(43) Pub. Date: Mar. 6, 2025

(54) BANDWIDTH TUNING USING SINGLE-INPUT MULTIPLE-OUTPUT LOW-NOISE AMPLIFIER

(71) Applicant: TEXAS INSTRUMENTS INCORPORATED, Dallas, TX (US)

(72) Inventors: Debapriya Sahu, Bangalore (IN); Radhika Juluri, Bangalore (IN); Meghna Agrawal, Bangalore (IN)

(21) Appl. No.: 18/462,083

(22) Filed: Sep. 6, 2023

(51) Int. Cl. H03F 3/24; H03F 1/08; H04B 1/04

(52) U.S. Cl. CPC H03F 3/245; H03F 1/086; H04B 1/0458; H03F 2200/06; H03F 2200/294; H04B 2001/0416

(57) ABSTRACT

Embodiments disclosed herein relate to impedance matching for outputting wide-band signals in radio frequency applications. In an example, a circuit including a low-noise amplifier (LNA) sub-circuit and a tuning sub-circuit is provided. The LNA sub-circuit is configured to couple to an antenna and includes a transistor that includes a gate, a source, and a drain, a first inductor that includes a first terminal configured to couple to the antenna and includes a second terminal, a second inductor that includes a first terminal coupled to the first terminal of the first inductor and includes a second terminal coupled to the gate of the transistor, and a third inductor that includes a first terminal coupled to the source of the transistor and includes a second terminal. The tuning sub-circuit is coupled to the source of the transistor.

### TECHNICAL FIELD

This relates generally to radio frequency circuits, and more particularly, to using a single-input, multiple-output low-noise amplifier for impedance matching of wide-band outputs.

### BACKGROUND

Radio frequency (RF) circuits are often used in electronic systems for communications applications. RF circuits can receive and transmit radio signals at varying frequencies and with varying gain based on their design. In various examples, RF circuits can receive a signal from an antenna and transmit a different signal, such as at a different bandwidth, downstream.

In order to receive and transmit RF signals, RF circuits often include one or more stages of inductors to perform impedance transformation and matching. For example, an RF circuit may include a pair of inductors coupled in series to output signals of different bandwidths. In another example, an RF circuit may include a pair of conductors coupled in parallel to output such signals of different bandwidths. However, these solutions with multiple inductors with shunt or series movements often require large amounts of area on chips, which increases costs and decreases flexibility in design. Additionally, using large areas on a chip to provide impedance matching can introduce large insertion loss, which impacts noise in the RF circuit.

Some RF circuits may also be configured to perform signal reception and transmission from a single pin. This may be referred to as port combining. Such solutions may reduce design area requirements on the printed circuit board; however, these implementations are only used with narrow-band frequencies.

Other RF circuits may introduce switchable inductor structures to output wide-band signals. Switchable inductors may include a switch between two inductors that allow a system to change between an inductor having one inductance and another inductor having a different inductance, which may allow the system to output signals in different frequency bands. Problematically, such solutions work by compromising gain on one or all of the frequency bands that can be output.

### SUMMARY

Various embodiments disclosed herein relate to radio frequency (RF) circuits, and more particularly, to using a port-combined RF system to provide impedance transformation, impedance matching, and wide-band matching. An RF system may include both a low-noise amplifier (LNA) sub-circuit and a wide-band matching sub-circuit that can, in combination, receive an antenna signal, amplify and match the impedance of the antenna signal, and output a signal at two or more different wide-band frequencies based on upstream and/or downstream requirements.

In an example, a circuit is provided. The circuit includes a low-noise amplifier (LNA) sub-circuit and a tuning sub-circuit. The LNA sub-circuit is configured to couple to an antenna and includes a transistor that includes a gate, a source, and a drain, a first inductor that includes a first terminal configured to couple to the antenna and includes a second terminal, a second inductor that includes a first terminal coupled to the first terminal of the first inductor and includes a second terminal coupled to the gate of the transistor, and a third inductor that includes a first terminal coupled to the source of the transistor and includes a second terminal. The tuning sub-circuit is coupled to the drain of the transistor.

This Summary is provided to introduce a selection of concepts in a simplified form that are further described below in the Detailed Description. It may be understood that this Summary is not intended to identify key features or essential features of the claimed subject matter, nor is it intended to be used to limit the scope of the claimed subject matter.

### BRIEF DESCRIPTION OF THE DRAWINGS

FIGS. 1A and 1B illustrate impedance and bandwidth matching systems that may be used in accordance with an embodiment.

FIG. 2 illustrates aspects of conductive features used in an impedance and bandwidth matching system in accordance with an embodiment.

FIG. 3 illustrates an example graphical representation related to conjugate matching with respect to impedance in accordance with an embodiment.

FIG. 4 illustrates an example graphical representation related to gain produced by an impedance matching sub-circuit in accordance with an embodiment.

The drawings are not necessarily drawn to scale. In the drawings, like reference numerals designate corresponding parts throughout the several views. In some embodiments, components or operations may be separated into different blocks or may be combined into a single block.

### DETAILED DESCRIPTION

Discussed herein are enhanced components, techniques, and systems related to radio frequency (RF) circuits, and more particularly, to producing multiple wide-band outputs using a port-combined low-noise amplifier (LNA) sub-circuit and wide-band matching sub-circuit. Often, RF circuits are designed to receive and transmit radio signals at varying frequencies and with variable gain. For example, RF circuits use antenna signals as inputs and use electronic components to output different signals, such as at different bandwidths, to downstream systems.

Existing RF circuit designs may use different pairs of inductors, whether coupled as shunt inductors, series inductors, or switching inductors, however, these solutions require large amounts of area on chips and still fail to provide impedance matching without significant insertion loss, noise, or other issues. Wide-band matching subsystems of existing RF circuits do not remedy such losses, and in fact, may still only be used in narrow-band applications. Thus, an RF circuit is needed that can provide gain sufficient to de-sense noise in the system, match the impedance of the antenna signal, and output a signal at two or more wide-band frequencies.

Disclosed herein is an RF circuit that includes both an LNA sub-circuit and a wide-band matching sub-circuit. The LNA sub-circuit includes shunt and series inductors that provide impedance transformation and matching and a transistor that provides gain sufficient to produce wide-band outputs. The wide-band matching sub-circuit includes multiple inductor-capacitor (LC) circuits that can be selectively chosen to output one of multiple wide-band signals. Advantageously, the disclosed RF circuit can perform impedance matching using single-coupled inductor coils to reduce noise, design area required, and insertion loss, while also improving gain and wide-band matching using magnetically-isolated LC circuits to improve range tuning for wide-band applications.

In an example embodiment, a circuit is provided. The circuit includes a low-noise amplifier (LNA) sub-circuit and a tuning sub-circuit. The LNA sub-circuit is configured to couple to an antenna and includes a transistor that includes a gate, a source, and a drain, a first inductor that includes a first terminal configured to couple to the antenna and includes a second terminal, a second inductor that includes a first terminal coupled to the first terminal of the first inductor and includes a second terminal coupled to the gate of the transistor, and a third inductor that includes a first terminal coupled to the source of the transistor and includes a second terminal. The tuning sub-circuit is coupled to the drain of the transistor.

In another example embodiment, a circuit is provided. The circuit includes a first capacitor, a second capacitor, a transmitter sub-circuit, a low-noise amplifier (LNA) sub-circuit, and a tuning sub-circuit. The first capacitor is configured to couple to an antenna. The second capacitor is coupled to the first capacitor and to the LNA sub-circuit. The transmitter sub-circuit is coupled to the first capacitor and to the LNA sub-circuit. The transmitter sub-circuit is coupled in parallel with the second capacitor and includes a power amplifier and a balun. The LNA sub-circuit includes a transistor that includes a gate, a source, and a drain, a first inductor that includes a first terminal configured to couple to the antenna via the first capacitor and the second capacitor and includes a second terminal, a second inductor that includes a first terminal coupled to the first terminal of the first inductor and includes a second terminal coupled to the gate of the transistor, and a third inductor that includes a first terminal coupled to the source of the transistor and includes a second terminal. The tuning sub-circuit is coupled to the drain of the transistor.

In yet another example embodiment, a low-noise amplifier (LNA) circuit is provided. The LNA circuit includes a first inductor that includes a first set of conductive features arranged in rings, a second inductor that includes a second set of conductive features arranged in rings that encircle the first set of conductive features, and a third inductor that includes a third set of conductive features proximate to the second set of conductive features and disposed such that the second set of conductive features is between the first set of conductive features and the third set of conductive features. The second set of conductive features includes a first terminal configured to couple to an antenna and a second terminal coupled to a gate of a transistor. The first set of conductive features includes a first terminal configured to couple to the antenna and coupled to the first terminal of the second set of conductive features and a second terminal coupled to receive a bias voltage and coupled to a first ground node. The third set of conductive features includes a first terminal coupled to a source of the transistor and a second terminal coupled to a second ground node.

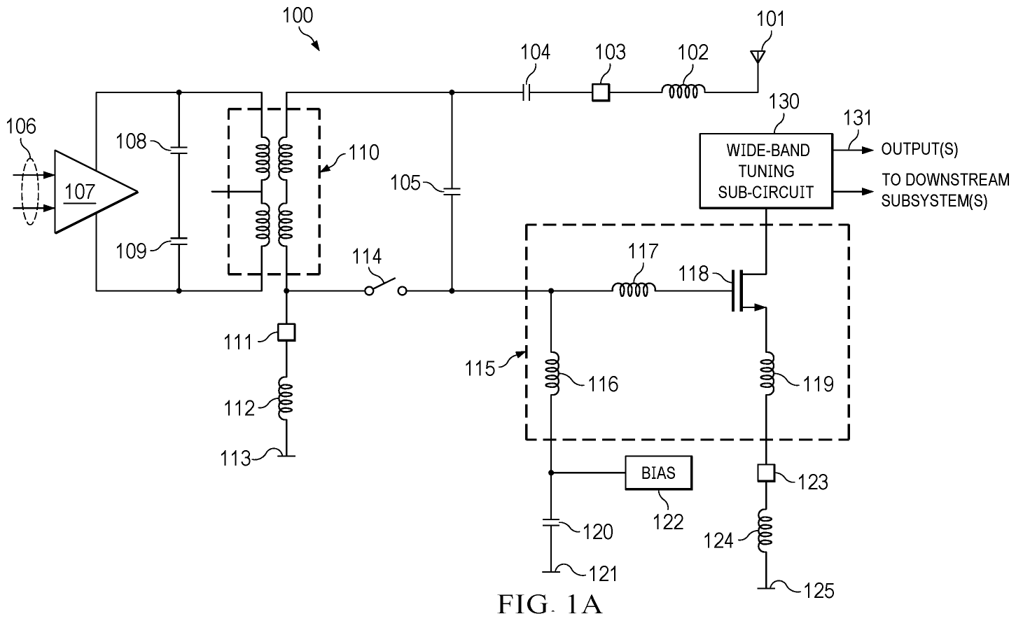

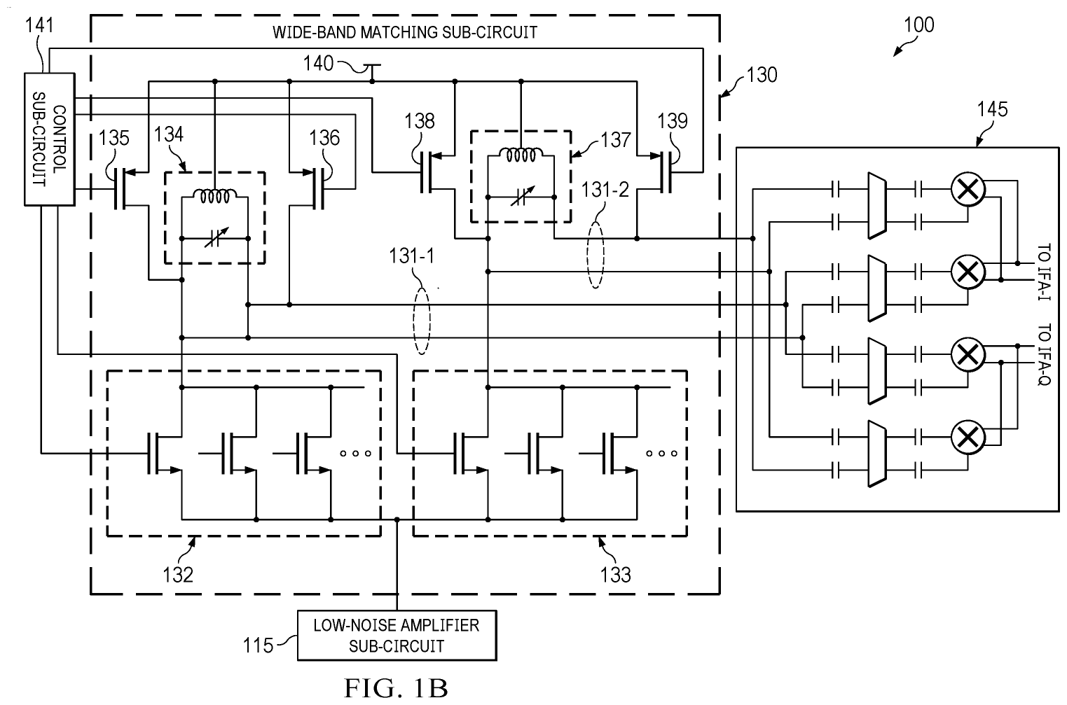

FIGS. 1A and 1B illustrate an impedance and bandwidth matching system that may be used in accordance with an embodiment. FIG. 1A includes system 100, which includes antenna 101, power amplifier 107, low-noise amplifier (LNA) sub-circuit 115, and wide-band tuning sub-circuit 130. LNA sub-circuit 115 further includes shunt inductor 116, capacitor 120, bias 122, gate inductor 117, transistor 118, and source inductor 119. FIG. 1B also includes system 100, and more particularly, includes details of wide-band tuning sub-circuit 130, and includes control sub-circuit 141 and downstream sub-circuit 145. Wide-band tuning sub-circuit 130 further includes cascode arrays 132 and 133, inductor-capacitor (LC) circuits 129 and 132, switches 130, 131, 133, and 134, and power supply 140. Wide-band tuning sub-circuit 130 is fed an impedance-matched signal from LNA sub-circuit 115 and provides outputs 131 to downstream sub-circuit 145 based on signals provided to components of wide-band tuning sub-circuit 130 by control sub-circuit 141.

System 100 is representative a circuit capable of receiving a signal from antenna 101, amplifying the signal and matching the impedance of the signal, and outputting a signal at various wide-band bandwidths. For example, system 100 can produce an output signal having a bandwidth between 5-6 GHz or an output signal having a bandwidth between 6-7 GHz. System 100 can include various electrical components coupled together to receive the signal from antenna 101 and provide such functionality. Such components include several inductors, capacitors, transistors, amplifiers, switches, and the like.

Referring first to FIG. 1A, antenna 101 is representative of an antenna capable of receiving signals from a radio or other device and converting the signals to electrical currents provided to components of system 100. Antenna 101 may operate in various bandwidths and radio frequencies, such as narrow-band and/or wide-band.

In system 100, inductor 102 is coupled to receive a signal from antenna 101. Inductor 102 is coupled in series with capacitor 104 at pin 103. Pin 103 may indicate an input/output port of a chip (e.g., an external conductor of the chip that couples to a printed circuit board). Accordingly, inductor 102 and antenna 101 may be off-chip. Capacitor 104 is further coupled to provide the signal through two separate branches: one including capacitor 105 and another including balun 110.

In various examples, the antenna 101 may be shared by a transmitter and a receiver. In a first example, power amplifier 107 and balun 110 can be included as a transmitter sub-circuit to amplify a signal for transmission via the antenna. Balun 110 is representative of an electrical device that can provide an interface between power amplifier 107 and LNA sub-circuit 115. For example, balun 110 may include multiple inductors forming a choke, such as a common-mode choke (CMC), that can filter out noise from power amplifier 107 or match the power amplifier 107 to the antenna. Balun 110 is fed by power amplifier 107 and can provide an amplified signal downstream to LNA sub-circuit 115, among other components. Power amplifier 107 is fed inputs 106, applies a gain to inputs 106, and provides a set of amplified signals to an LC circuit formed between capacitors 108 and 109 and balun 110. The amplification provided by power amplifier 107 can allow balun 110 to amplify a signal received from a transmitting device for transmission via antenna 101 through capacitor 104 when switch 114 is closed. However, when switch 114 is open, the signal passes to off-chip components. Alternatively, in a second example, power amplifier 107 may not be used. In such cases, balun 110 may include two inductors coupled in series and coupled to receive the antenna signal and provide the signal to inductor 112 and switch 114. In this way, switch 114 may provide port-combining capabilities for system 100. However, balun 110 and power amplifier 107 may act as a load with respect to the receiver in such port-combined arrangements.

LNA sub-circuit 115 is representative of a low-noise amplifier capable of amplifying the signal from antenna 101 while minimizing degradation of the signal-to-noise ratio of the signal and matching the impedance of the signal to improve power transmission over wide-bands. LNA sub-circuit 115 includes various inductors (shunt inductor 116, gate inductor 117, and source inductor 119) and transistor 118.

Together, shunt inductor 116, gate inductor 117, and source inductor 119 can match the impedance of the signal from antenna 101 based on the topology of LNA sub-circuit 115. More specifically, shunt inductor 116 and gate inductor 117 each have a terminal coupled to a node fed by capacitor 105 and balun 110. Shunt inductor 116 has another terminal coupled to receive a voltage from bias 122. This terminal of shunt inductor 116 is coupled in series with capacitor 120, which is coupled to ground node 121. Gate inductor 117 has another terminal coupled in series with a gate of transistor 118. Gate inductor 117 receives the antenna signal and feeds the signal to the gate of transistor 118. The signal can flow through a source of transistor 118, which can be coupled to source inductor 119. Source inductor 119 is further coupled in series with inductor 124, which is coupled to ground node 125. In some examples, inductor 124 is a package inductor located outside LNA sub-circuit 115. In such examples, such as the one illustrated by FIG. 1A, inductor 124 is coupled to source inductor 119 at pin 123. However, inductor 124 may also be combined with source inductor 119 as a single inductor on-chip, or located within LNA sub-circuit 115.

In this topology, shunt inductor 116 can provide a first conjugate shift of the impedance of the antenna signal. Gate inductor 117 can provide a second conjugate shift of the impedance of the antenna signal. Then, source inductor 119 can provide a third conjugate shift of the impedance of the antenna signal and/or provide a real part for reception of the signal. Following the third conjugate shift by source inductor 119, LNA sub-circuit 115 may have achieved maximum power transfer of the signal from antenna 101, such that the power of the signal flowing through transistor 118 may be equal, or approximately equal, to the power of the signal obtained from antenna 101 and received at LNA sub-circuit 115.

Transistor 118 can be coupled to provide the impedance-matched signal to wide-band tuning subsystem 125 at the drain of transistor 118. In various examples, transistor 118 may be a metal-oxide-semiconductor field-effect transistor (MOSFET), including a gate, a source, and a drain. In other examples, however, transistor 118 may be another type of transistor.

Referring next to FIG. 1B and continuing from the discussion above, LNA sub-circuit 115, and more specifically, transistor 118 of LNA sub-circuit 115, is coupled to provide the impedance-matched signal to two cascode arrays of transistors, cascode array 132 and cascode array 133, of wide-band tuning sub-circuit 130. As illustrated in FIG. 1B. cascode array 132 and cascode array 133 each include three transistors arranged in parallel. However, additional or fewer numbers of transistors may be included in cascode array 132 and/or cascode array 133. Cascode array 132 can be coupled to provide the impedance-matched signal to LC circuit 134. Cascode array 133 can be coupled to provide the impedance-matched signal to LC circuit 137.

LC circuits 134 and 137 may each include a variable capacitor and an inductor coupled in parallel with respect to one another. In other examples, however, the inductor and capacitor of LC circuit 134 and 132 may be arranged in a different topology. The values of the capacitor and inductor may be selected based on desired output gains and bandwidths of respective circuits. In various examples, LC circuit 134 may be configured to tune the impedance-matched signal from antenna 101 to a bandwidth of approximately 5-6 GHZ (i.e., output 131-1), and LC circuit 137 may be configured to tune the impedance-matched signal to a bandwidth of approximately 6-7 GHZ (i.e., output 131-2). LC circuits 134 and 137 may be further coupled to power supply 140. In some examples, power supply 140 may be coupled at the inductors of LC circuits 134 and 137, such as at a center tap, or midpoint terminal, of the inductors. In other examples, power supply 140 may be coupled at a terminal of the inductors, among other nodes of LC circuits 134 and 137.

Power supply 140 is included in wide-band tuning sub-circuit 130 to provide a current to LC circuits 134 and 137, among other elements of wide-band tuning sub-circuit 130. In various examples, power supply 140 may provide an internal or external voltage with respect to system 100 (e.g., Vad). LC circuit 134 is coupled to power supply 140 and cascode array 132. LC circuit 137 is coupled to power supply 140 and cascode array 133. Accordingly, LC circuits 134 and 137 are coupled in parallel with respect to each other.

In various examples, only one of LC circuits 134 and 137 may be “active” at a given time, or in other words, producing output 131-1 or 131-2, respectively. More particularly, when LC circuit 134 is configured to provide output 131-1, LC circuit 137 may be configured to not provide output 131-2 by coupling both end terminals of the inductor and both end terminals of the capacitor to the power supply 140. And conversely, when LC circuit 137 is configured to provide output 131-2, LC circuit 134 may be configured to not provide output 131-1 by coupling both end terminals of the inductor and both end terminals of the capacitor to the power supply 140.

To control which LC circuit is active, wide-band tuning sub-circuit 130 may include control sub-circuit 141 coupled to switches 135, 136, 138, and 139 and cascode arrays 132 and 133. More specifically, control sub-circuit 141 may be coupled to a gate of each of switches 135, 136, 138, and 139 and to a gate of each transistor of cascode arrays 132 and 133. Control sub-circuit 141 is representative of one or more processors, processing units (e.g., CPUs), or the like, capable of providing signals to components of wide-band tuning sub-circuit 130 to control operations thereof.

Switches 135, 136, 138, and 139 each include a transistor (e.g., an n-type transistor, a p-type transistor). Switches 135 and 136 can be coupled to power supply 140 and cascode array 132 and in parallel with LC circuit 134. Switches 138 and 139 can be coupled to power supply 140 and cascode array 133 and in parallel with LC circuit 137.

Switches 130, 131, 133, and 134 can be “opened” or “closed” based on signals provided to gates of the switches by control sub-circuit 141. In use, switches 135 and 136 may control operation of LC circuit 134, and switches 138 and 139 may control operation of LC circuit 137.

In a first example, control sub-circuit 141 may control wide-band tuning sub-circuit 130 to provide output 131-1, an output signal in the 5-6 GHz band, via LC circuit 134. More specifically, control sub-circuit 141 may provide a signal to switches 135 and 136 to control switches 135 and 136 to operate in an open state, or as open switches, and control sub-circuit 141 may provide a signal to switches 138 and 139 to control switches 138 and 139 to operate in the closed state, or as closed switches. Further, control sub-circuit 141 may provide signals to transistors of cascode array 133 to prevent the impedance-matched signal from flowing through cascode array 133 to LC circuit 137. Based on the states of the switches and the current flowing through cascode array 132, control sub-circuit 141 may allow LC circuit 134 to generate output 131-1 and prevent LC circuit 137 from outputting a signal in the 6-7 GHz band (i.e., output 131-2).

In a second example, control sub-circuit 141 may control wide-band tuning sub-circuit 130 to provide output 131-2, an output signal in the 6-7 GHz band, via LC circuit 137. More specifically, control sub-circuit 141 may provide a signal to switches 135 and 136 to control switches 135 and 136 to operate in the closed state, and control sub-circuit 141 may provide a signal to switches 138 and 139 to control switches 138 and 139 to operate in the open state. Further, control sub-circuit 141 may provide signals to transistors of cascode array 132 to prevent the impedance-matched signal from flowing through cascode array 132 to LC circuit 134. Based on the states of the switches and the current flowing through cascode array 133, control sub-circuit 141 may allow LC circuit 137 to generate output 131-2 and prevent LC circuit 134 from outputting output 131-2.

The gain of each of output 131-1 and 131-2 may be controlled by cascode arrays 132 and 133, respectively. For example, a maximum gain can be applied to output 131-1 when control sub-circuit 141 prevents current (i.e., the signal from LNA sub-circuit 115) from flowing through cascode array 133, such as by providing signals to the transistors of cascode array 133 to block current flow. Accordingly, all of the current may flow through cascode array 132 and to LC circuit 134. The gain of output 131-1 can be reduced, however, if control sub-circuit 141 allows an amount of current to flow through cascode array 133, which would cause the current to be split among cascode array 132 and cascode array 133. Similarly, a maximum gain can be applied to output 131-2 if control sub-circuit 141 prevents current from flowing through cascode array 132. However, a different gain may be applied to output 131-2 based on the amount of current split among cascode array 132 and cascode array 133, which may be similarly controlled by control sub-circuit 141.

LC circuits 134 and 137 can further be coupled to provide outputs 131-1 and 131-2. respectively, to downstream sub-circuit 145. Downstream sub-circuit 145 may include various electrical components, such as transconductance amplifiers (TA) that may be coupled to receive outputs 131-1 and/or 131-2 from LC circuits 134 and 137, respectively. Downstream sub-circuit 145 may further be coupled with other sub-circuits, systems, or the like (not shown).

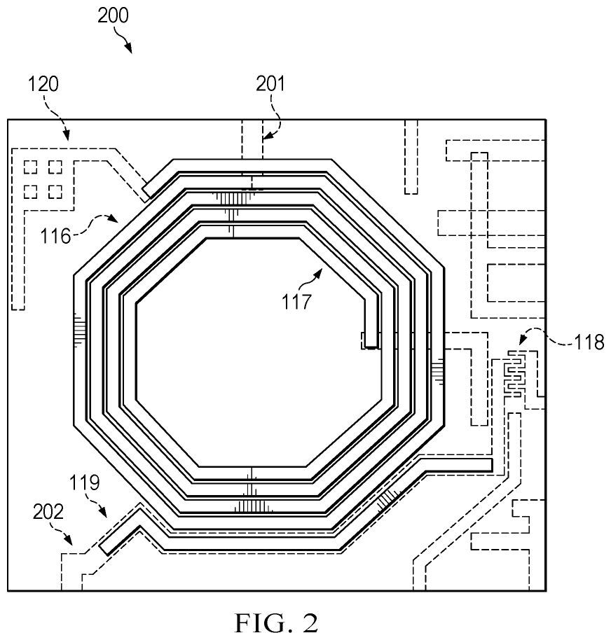

FIG. 2 illustrates aspects of conductive features used in an impedance and bandwidth matching system in accordance with an embodiment. FIG. 2 illustrates system-on-chip (SoC) architecture 200, which references elements of FIG. 1. SoC architecture 200 includes capacitor 120, shunt inductor 116, node 201, gate inductor 117, transistor 118, source inductor 119, and pin connection 202. SoC architecture 200 may represent a physical implementation of elements of an impedance and bandwidth matching system, such as LNA sub-circuit 115 of system 100 of FIG. 1A, among other elements.

SoC architecture 200 depicts an example layout of conductive features inside a chip (e.g., silicon die). The features included in SoC architecture 200 may include traces of conductive material etched or embedded in a chip. Such features, when coupled together and provided a signal from an antenna (e.g., antenna 101 of FIG. 1A), may perform functionality of LNA sub-circuit 115.

SoC architecture 200 includes capacitor 120 as depicted in the top left corner of the illustration in FIG. 2. Capacitor 120 may include a set of conductive features including two terminals. At a first terminal, capacitor 120 may be coupled to a ground node (ground node 121 of FIG. 1A). At a second terminal, capacitor 120 may be coupled to shunt inductor 116.

Shunt inductor 116 may include a set of conductive features arranged in a ring formation (e.g., concentric rings, staggered center rings). Shunt inductor 116 may also include two terminals. A first terminal may be coupled with capacitor 120, and a second terminal may be coupled with both node 201 and gate inductor 117. Node 201 represents a node where terminals of gate inductor 117 and shunt inductor 116 meet. In some embodiments, shunt inductor 116 and gate inductor 117 may be a single set of conductive features (i.e., a single-coupled coil). However, in other embodiments, shunt inductor 116 and gate inductor 117 may be separate sets of conductive features (as indicated by the dashed line in FIG. 2), such as a first set of conductive features located on one layer of the chip and a second set of conductive features located on another layer of the chip.

Gate inductor 117 may include a set of conductive features arranged in another ring formation that is encircled by shunt inductor 116. Gate inductor 117 includes two terminals. A first terminal of gate inductor 117 is coupled to capacitor 120 and shunt inductor 116, and a second terminal of gate inductor 117 is coupled to transistor 118.

Transistor 118 may include a set of conductive features including a gate terminal, a source terminal, and a drain terminal. The gate terminal of transistor 118 can be coupled to gate inductor 117, the source terminal of transistor 118 can be coupled to source inductor 119, and the drain terminal of transistor 118 can be coupled to a wide-band matching sub-circuit, such as wide-band tuning sub-circuit 130 of FIGS. 1A and 1B.

Source inductor 119 may include a further set of conductive features arranged proximately to shunt inductor 116 and gate inductor 117 in such a way that shunt inductor 116 is between source inductor 119 and gate inductor 117 in system architecture 200. Source inductor 119 may include a first terminal coupled to the source of transistor 118 and a second terminal coupled to pin 123 (of FIG. 1A) via pin connection 202. Additional components, such as inductor 124 shown in FIG. 1A, may be off-chip and coupled to pin 123 via pin connection 202.

In this arrangement, shunt inductor 116 and gate inductor 117 may form a single-coupled coil that acts as an inductor in an impedance matching system (e.g., LNA sub-circuit 115). Shunt inductor 116 and gate inductor 117 may be mutually coupled, and the two inductors may be coupled closely in distance to source inductor 119. Advantageously, the three inductors can provide conjugate matching, such that the power of an antenna signal provided from an antenna through node 201 to shunt inductor 116 to gate inductor 117 to transistor 118 and to source inductor 119 may be equal, or approximately equal, when fed to the wide-band matching sub-circuit. Not only may this allow for maximum power transfer to the wide-band matching sub-circuit, but also this arrangement may allow the wide-band matching sub-circuit to receive wide-band frequencies.

In other examples, system architecture 200 may include additional or fewer components, which may be arranged in a different layout. For example, the positioning of various conductive features may be different. Nevertheless, shunt inductor 116, gate inductor 117, and source inductor 119 may be included to conjugate shift and perform impedance matching.

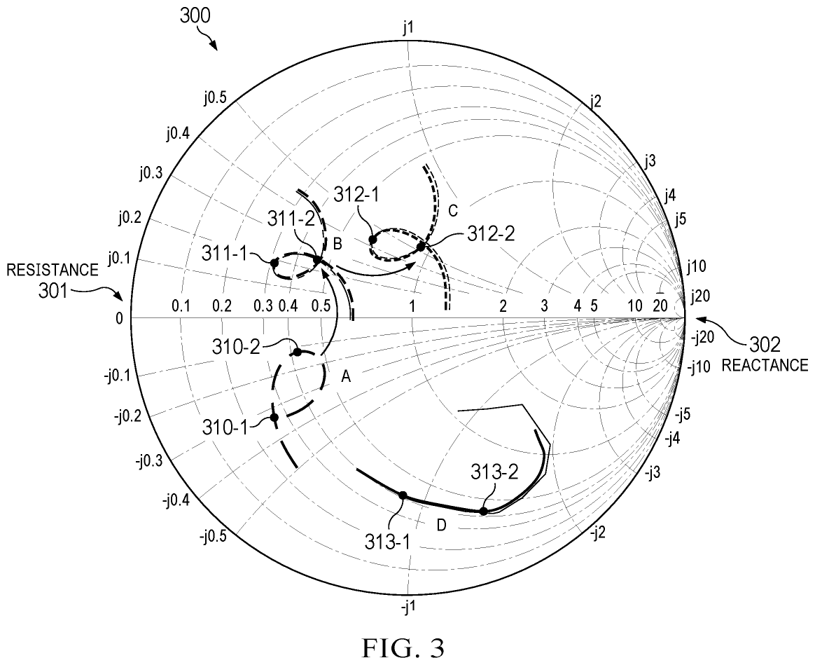

FIG. 3 illustrates an example graphical representation related to conjugate matching with respect to impedance in accordance with an embodiment. FIG. 3 shows graphical representation 300, which includes sample results with respect to complex impedance of an antenna signal measured at different nodes of system 100 of FIG. 1A, such as at switch 114, shunt inductor 116, gate inductor 117, and source inductor 119.

Outputs 310-1, 310-2, 311-1, 311-2, 312-1, 312-2, 313-1, and 313-2 are representative of pairs of impedance values measured in an impedance and bandwidth matching system, such as at different points of LNA sub-circuit 115 of system 100. Outputs 310-1 and 310-2 (collectively referred to as outputs 310) may represent complex impedance values measured at a first terminal of shunt inductor 116, or in other words, where switch 114 and capacitor 105 meet shunt inductor 116. Outputs 310 may reflect an impedance of the signal provided by antenna 101 of system 100. Outputs 311-1 and 311-2 (collectively referred to as outputs 311) may represent complex impedance values measured at a first terminal of gate inductor 117 following a first conjugate shift by shunt inductor 116. Output 312-1 and 312-2 (collectively referred to as outputs 312) may represent complex impedance values measured at a second terminal of gate inductor 117, or at the gate of transistor 118, following a second conjugate shift by gate inductor 117. Outputs 313-1 and 313-2 (collectively referred to as outputs 313) may represent complex impedance values measured at source inductor 119 following a third conjugate shift by source inductor 119.

As illustrated, following the first conjugate shift by shunt inductor 116, outputs 311-1 and 311-2 can include values with approximately equal resistance 301 as outputs 310-1 and 310-2, respectively, but reflected to a positive reactance 302. Following the second conjugate shift by gate inductor 117, outputs 312-1 and 312-2 can include values with approximately equal reactance 302 as outputs 311-1 and 311-2, respectively, but reflected to a different resistance 301. Following the third conjugate shift by source inductor 119, outputs 313-1 and 313-2 can include values with approximately equal resistance 301 as outputs 312-1 and 312-2, respectively, but reflected to a different, negative reactance 302. Accordingly, the combination of shunt inductor 116, gate inductor 117, and source inductor 119 can provide conjugate shifting to match an impedance of an input, antenna signal.

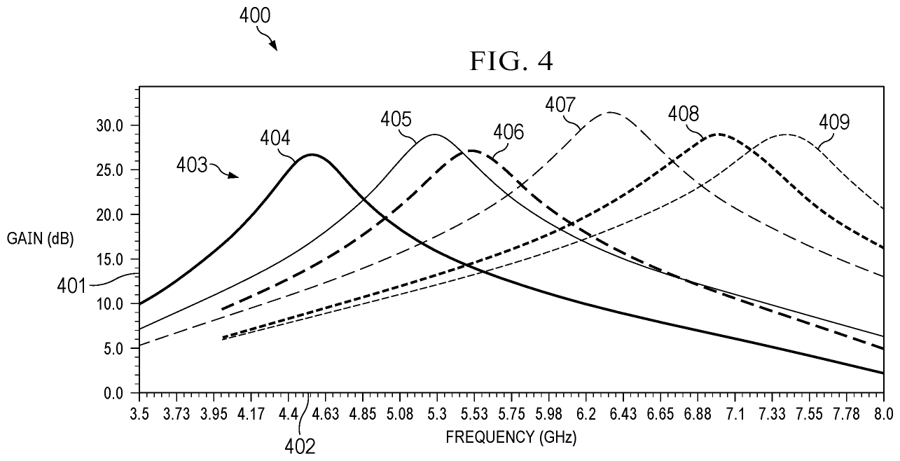

FIG. 4 illustrates an example graphical representation related to gain 401 relative to frequency 402 produced by an impedance matching sub-circuit in accordance with an embodiment. FIG. 4 shows graphical representation 400, which includes sample results with respect to gain 401 and frequency 402. Outputs 403, 404, 405, 406, 407, 408, and 409 shown in graphical representation 400 may be produced by components of an impedance and bandwidth matching system, such as LC circuits 129 and/or 132 of wide-band tuning sub-circuit 130 of system 100 of FIGS. 1A and 1B.

Outputs 403, 404, 405, and 407 may reflect sample results of gain 401 relative to frequency 402 produced by LC circuit 134 (e.g., output 131-1). As illustrated, outputs 403, 404, 405, and 407 include a gain 401 between 4.5 GHZ and 6.3 GHZ at varying frequencies. In various examples, gain 401 of each of outputs 403, 404, 405, and 407 may be realized by adjusting current flow through cascode arrays 132 and 133 via control sub-circuit 141. For example, a smaller gain of output 131-1 may be achieved based on signals provided by control sub-circuit 141 to transistors of cascode array 133 that allow current (i.e., the impedance-matched signal provided by LNA sub-circuit 115) to flow through cascode array 133 as well as cascode array 132. However, the gain of output 131-1 may be increased or maximized based on different signals provided by control sub-circuit 141 to the transistors of cascode array 133 that prevent current from flowing through cascode array 133. Therefore, in such cases, all current may flow through cascode array 132 and to LC circuit 134, which may increase the gain of output 131-1. Additionally, these values may each have a different frequency 402 with respect to one another based on inductor values chosen for LC circuit 134. Despite changing frequency 402, though, output 131-1 can range from approximately 5-6 GHz as desired.

Outputs 406, 408, and 409 may reflect sample results of gain 401 relative to frequency 402 produced by LC circuit 137 (e.g., output 131-2). As illustrated, outputs 406, 408, and 409 include a gain 401 between 5.5 GHZ and 7.4 GHz at varying frequencies. In various examples, gain 401 of each of outputs 406, 408, and 409 may be realized by adjusting current flow through cascode arrays 132 and 133 via control sub-circuit 141. For example, a smaller gain of output 131-2 may be achieved based on signals provided by control sub-circuit 141 to transistors of cascode array 132 that allow current (i.e., the impedance-matched signal provided by LNA sub-circuit 115) to flow through cascode array 132 as well as cascode array 133. However, the gain of output 131-2 may be increased or maximized based on different signals provided by control sub-circuit 141 to the transistors of cascode array 132 that prevent current from flowing through cascode array 132. Therefore, in such cases, all current may flow through cascode array 133 and to LC circuit 137, which may increase the gain of output 131-2. Additionally, these values may each have a different frequency 402 with respect to one another based on inductor values chosen for LC circuit 137. Despite changing frequency 402, output 131-2 can range from approximately 6-7 GHz as desired.

While some examples provided herein are described in the context of an impedance and wide-band matching system, circuit, sub-circuit, component, device, element, architecture, or environment, the systems, circuits, and methods described herein are not limited to such embodiments and may apply to a variety of other processes, systems, applications, devices, and the like.

Unless the context clearly requires otherwise, throughout the description and the claims, the words “comprise,” “comprising.” and the like are to be construed in an inclusive sense, as opposed to an exclusive or exhaustive sense; that is to say, in the sense of “including, but not limited to.” As used herein, the terms “connected,” “coupled,” or any variant thereof means any connection or coupling, either direct or indirect, between two or more elements; the coupling or connection between the elements can be physical, logical, or a combination thereof. Additionally, the words “herein,” “above,” “below,” and words of similar import, when used in this application, refer to this application as a whole and not to any particular portions of this application. Where the context permits, words in the above Detailed Description using the singular or plural number may also include the plural or singular number respectively. The word “or,” in reference to a list of two or more items, covers all of the following interpretations of the word: any of the items in the list, all of the items in the list, and any combination of the items in the list.

The phrases “in some embodiments,” “according to some embodiments,” “in the embodiments shown,” “in other embodiments,” and the like generally mean the particular feature, structure, or characteristic following the phrase is included in at least one implementation of the present technology, and may be included in more than one implementation. In addition, such phrases do not necessarily refer to the same embodiments or different embodiments.

The above Detailed Description of examples of the technology is not intended to be exhaustive or to limit the technology to the precise form disclosed above. While specific examples for the technology are described above for illustrative purposes, various equivalent modifications are possible within the scope of the technology, as those skilled in the relevant art will recognize. For example, while processes or elements are presented in a given order, alternative implementations may perform routines having steps, or employ systems having elements or components, in a different order, and some processes or elements may be deleted. moved, added, subdivided, combined, and/or modified to provide alternative or subcombinations. Each of these processes or elements may be implemented in a variety of different ways. Further any specific numbers noted herein are only examples: alternative implementations may employ differing values or ranges.

The teachings of the technology provided herein can be applied to other systems, not necessarily the system described above. The elements and acts of the various examples described above can be combined to provide further implementations of the technology. Some alternative implementations of the technology may include not only additional elements to those implementations noted above, but also may include fewer elements.

These and other changes can be made to the technology in light of the above Detailed Description. While the above description describes certain examples of the technology, and describes the best mode contemplated, no matter how detailed the above appears in text, the technology can be practiced in many ways. Details of the system may vary considerably in its specific implementation, while still being encompassed by the technology disclosed herein. As noted above, particular terminology used when describing certain features or aspects of the technology should not be taken to imply that the terminology is being redefined herein to be restricted to any specific characteristics, features, or aspects of the technology with which that terminology is associated. In general, the terms used in the following claims should not be construed to limit the technology to the specific examples disclosed in the specification, unless the above Detailed Description section explicitly defines such terms. Accordingly, the actual scope of the technology encompasses not only the disclosed examples, but also all equivalent ways of practicing or implementing the technology under the claims.

To reduce the number of claims, certain aspects of the technology are presented below in certain claim forms, but the applicant contemplates the various aspects of the technology in any number of claim forms. For example, while only one aspect of the technology is recited as a computer-readable medium claim, other aspects may likewise be embodied as a computer-readable medium claim, or in other forms, such as being embodied in a means-plus-function claim. Any claims intended to be treated under 35 U.S.C. § 112(f) will begin with the words “means for” but use of the term “for” in any other context is not intended to invoke treatment under 35 U.S.C. § 112(f). Accordingly, the applicant reserves the right to pursue additional claims after filing this application to pursue such additional claim forms, in either this application or in a continuing application.

What is claimed is:

1. A circuit, comprising:
a low-noise amplifier sub-circuit configured to couple to an antenna, wherein the low-noise amplifier sub-circuit comprises:
a transistor that includes a gate, a source, and a drain;
a first inductor that includes a first terminal configured to couple to the antenna and includes a second terminal;
a second inductor that includes a first terminal coupled to the first terminal of the first inductor and includes a second terminal coupled to the gate of the transistor; and
a third inductor that includes a first terminal coupled to the source of the transistor and includes a second terminal; and
a tuning sub-circuit coupled to the drain of the transistor.

2. The circuit of claim 1, wherein the low-noise amplifier sub-circuit is configured to couple to the antenna via a first capacitor configured to couple to the antenna and a second capacitor coupled to the first capacitor and to the low-noise amplifier sub-circuit.

3. The circuit of claim 2, wherein the low-noise amplifier sub-circuit is further configured to couple to the antenna via a transmitter sub-circuit coupled to the first capacitor, wherein the transmitter sub-circuit is coupled in parallel with the second capacitor and comprises a power amplifier and a balun.

4. The circuit of claim 3, wherein the transmitter sub-circuit further comprises a switch, and wherein the low-noise amplifier sub-circuit is further configured to couple to the antenna via the transmitter sub-circuit based on a state of the switch, and wherein the switch enables port-combining based on the state of the switch.

5. The circuit of claim 1, wherein the tuning sub-circuit comprises a first cascode array of transistors, a first LC circuit coupled to the first cascode array and a power supply, a first switch coupled to the first cascode array, the first LC circuit, and the power supply, a second switch coupled to the first cascode array, the first LC circuit, and the power supply, a second cascode array of transistor, a second LC circuit coupled to the second cascode array and the power supply, a third switch coupled to the second cascode array, the second LC circuit, and the power supply, and a fourth switch coupled to the second cascode array, the second LC circuit, and the power supply.

6. The circuit of claim 5, further comprising a control sub-circuit coupled to the first switch, the second switch, the third switch, the fourth switch, the first cascode array, and the second cascode array.

7. The circuit of claim 6, wherein the first LC circuit is configured to generate a first output based on the first switch being in an open state, the second switch being in the open state, the third switch being in a closed state, and the fourth switch being in the closed state, wherein the second LC circuit is configured to generate a second output based on the first switch being in the closed state, the second switch being in the closed state, the third switch being in the open state, and the fourth switch being in the open state, and wherein the control sub-circuit is configured to control the open state and the closed state of the first switch, the second switch, the third switch, and the fourth switch.

8. The circuit of claim 7, wherein the first gain comprises a bandwidth between 5-6 GHz, and wherein the second gain comprises a bandwidth between 6-7 GHz.

9. The circuit of claim 7, wherein the control sub-circuit is further configured to control a gain of the first output based on a state of the second cascode array and the gain of the second output based on the state of the first cascode array.

10. A circuit, comprising:
a first capacitor configured to couple to an antenna;
a second capacitor coupled to the first capacitor and to a low-noise amplifier sub-circuit;
a transmitter sub-circuit coupled to the first capacitor and to the low-noise amplifier sub-circuit, wherein the transmitter sub-circuit is coupled in parallel with the second capacitor, and wherein the transmitter sub-circuit comprises a power amplifier and a balun;
the low-noise amplifier sub-circuit comprising:
a transistor that includes a gate, a source, and a drain;
a first inductor that includes a first terminal configured to couple to the antenna via the first capacitor and the second capacitor and includes a second terminal;
a second inductor that includes a first terminal coupled to the first terminal of the first inductor and includes a second terminal coupled to the gate of the transistor; and
a third inductor that includes a first terminal coupled to the source of the transistor and includes a second terminal; and
a tuning sub-circuit coupled to the drain of the transistor.

11. The circuit of claim 10, wherein the transmitter sub-circuit further comprises a switch, and wherein the low-noise amplifier sub-circuit is further configured to couple to the antenna via the transmitter sub-circuit based on a state of the switch, and wherein the switch enables port-combining based on the state of the switch.

12. The circuit of claim 10, wherein the tuning sub-circuit comprises a first cascode array of transistors, a first LC circuit coupled to the first cascode array and a power supply, a first switch coupled to the first cascode array, the first LC circuit, and the power supply, a second switch coupled to the first cascode array, the first LC circuit, and the power supply, a second cascode array of transistor, a second LC circuit coupled to the second cascode array and the power supply, a third switch coupled to the second cascode array, the second LC circuit, and the power supply, and a fourth switch coupled to the second cascode array, the second LC circuit, and the power supply.

13. The circuit of claim 12, further comprising a control sub-circuit coupled to the first switch, the second switch, the third switch, the fourth switch, the first cascode array, and the second cascode array.

14. The circuit of claim 13, wherein the first LC circuit is configured to generate a first output based on the first switch being in an open state, the second switch being in the open state, the third switch being in a closed state, and the fourth switch being in the closed state, wherein the second LC circuit is configured to generate a second output based on the first switch being in the closed state, the second switch being in the closed state, the third switch being in the open state, and the fourth switch being in the open state, and wherein the control sub-circuit is configured to control the open state and the closed state of the first switch, the second switch, the third switch, and the fourth switch.

15. The circuit of claim 14, wherein the first gain comprises a bandwidth between 5-6 GHz, and wherein the second gain comprises a bandwidth between 6-7 GHz.

16. A low-noise amplifier circuit, comprising:
a first inductor that includes a first set of conductive features arranged in rings;
a second inductor that includes a second set of conductive features arranged in rings that encircle the first set of conductive features; and
a third inductor that includes a third set of conductive features proximate to the second set of conductive features and disposed such that the second set of conductive features is between the first set of conductive features and the third set of conductive features;
wherein the second set of conductive features comprises a first terminal configured to couple to an antenna and a second terminal coupled to a gate of a transistor;
wherein the first set of conductive features comprises a first terminal configured to couple to the antenna and coupled to the first terminal of the second set of conductive features and a second terminal coupled to receive a bias voltage and coupled to a first ground node; and
wherein the third set of conductive features comprises a first terminal coupled to a source of the transistor and a second terminal coupled to a second ground node.

17. The low-noise amplifier circuit of claim 16, wherein the first set of conductive features and the second set of conductive features form a single-coupled inductor coil, and wherein the third set of conductive features comprises one or more inductor coils.

18. The low-noise amplifier circuit of claim 16, further comprising the transistor that includes the gate, the source, and a drain.

19. The low-noise amplifier circuit of claim 18, wherein the drain of the transistor is coupled to a tuning sub-circuit, and wherein the tuning sub-circuit comprises a first cascode array of transistors, a first LC circuit coupled to the first cascode array, a first switch coupled to the first cascode array, the first LC circuit, and a power supply, a second switch coupled to the first cascode array, the first LC circuit, and the power supply, a second cascode array of transistor, a second LC circuit coupled to the second cascode array, a third switch coupled to the second cascode array, the second LC circuit, and the power supply, a fourth switch coupled to the second cascode array, the second LC circuit, and the power supply, and a control sub-circuit coupled to the first switch, the second switch, the third switch, the fourth switch, the first cascode array, and the second cascode array.

20. The low-noise amplifier circuit of claim 19, wherein the first LC circuit is configured to generate a first output based on the first switch being in an open state, the second switch being in the open state, the third switch being in a closed state, and the fourth switch being in the closed state, wherein the second LC circuit is configured to generate a second output based on the first switch being in the closed state, the second switch being in the closed state, the third switch being in the open state, and the fourth switch being in the open state, and wherein the control sub-circuit is configured to control the open state and the closed state of the first switch, the second switch, the third switch, and the fourth switch.
